(19) United States
(12) Patent Application Publication
(10) Pub. No.: US 2005/0079703 A1
(43) Pub. Date: Apr. 14, 2005

(54) Method for planarizing an interconnect structure

(75) Inventors: Hui Chen, Milpitas, CA (US); Chun Yan, San Jose, CA (US); Wai-Fan Yau, Los Altos, CA (US)

Correspondence Address: MOSER, PATTERSON & SHERIDAN, LLP;APPLIED MATERIALS INC, 595 SHREWSBURY AVE, SUITE 100, SHREWSBURY, NJ, 07702, US

(73) Assignee: Applied Materials, Inc.

(21) Appl. No.: 10/683,143

(22) Filed: Oct. 9, 2003

(51) Int. Cl. H01L 21/44; H01L 21/4763

(52) U.S. Cl. 438/633

(57) ABSTRACT

A method of forming an interconnect structure (e.g., copper interconnect structure, and the like) on a semiconductor substrate. The interconnect structure is formed by depositing within trenches and openings formed in an inter-metal dielectric (IMD) layer a barrier layer and a conductive material. Thereafter, the interconnect structure is planarized using a two-step process whereby excess conductive material on the IMD material is removed during the first step using a chemical mechanical polishing (CMD) process. In the second step the barrier layer is removed using a plasma etch process. The barrier layer is removed using a gas mixture including a halogen-containing gas.

### BACKGROUND OF THE INVENTION

1. Field of the Invention

The present invention generally relates to semiconductor substrate processing systems. More specifically, the present invention relates to a method for planarizing an interconnect structure in a semiconductor substrate processing system.

2. Description of the Related Art

In the semiconductor industry, much effort is spent in developing smaller integrated circuit (IC) devices with ever-increasing operating speeds. Among the factors affecting the operating speed of the IC devices is a dielectric constant for an inter-metal dielectric (IMD) layer of a wiring network for the IC device. To increase the operating speed of the IC devices, the IMD layers are typically formed using materials having dielectric constants less than about 4.0. Such materials are commonly referred to as low-k dielectric materials. Suitable low-k dielectric materials typically include carbon-doped dielectrics, such as organic doped silicon glass (OSG), fluorine doped silicon glass (FSG), organic polymers (e.g., benzocyclobutene, parylene, polytetrafluoroethylene, polyether, polyimide), and the like.

The wiring network for the IC devices generally includes a plurality of interconnect structures that are isolated from each other and the substrate by the IMD layers. Such structures are generally fabricated using a dual damascene technique including an insulator layer (e.g., inter-metal dielectric (IMD) layer) within which trenches and openings are etched to position conductive lines and contact holes, or vias. Thereafter, a barrier layer (e.g., layer comprising films of tantalum (Ta), titanium (Ti), tungsten (W), tantalum nitride (TaN), titanium nitride (TiN), tungsten nitride (WN), and the like) along with a metallic layer (e.g., copper (Cu) layer) are sequentially deposited to fill the trenches and openings to form a conductive interconnect structure. In a copper interconnect structure, the barrier layer improves adhesion between the low-k IMD layer (e.g., OSG layer) and a copper conductor, as well as impedes diffusion of copper and oxygen into the low-k material. The copper fills (metallizes) the trenches and openings in the IMD layer, thereby forming conductive lines and vias, respectively. During the metallization process (e.g., electroplating (ECP) metallization process) an excess amount of copper may be deposited onto the substrate.

Such excess copper, as well as the underlying barrier layer, are typically removed using a planarization process, such as a chemical-mechanical polishing (CMP) process. During the CMP process, the excess copper and barrier layer are removed from the substrate so that the conductor embedded in the IMD layer becomes coplanar with an exposed surface of such IMD layer. However, when the barrier layer is removed, compressive and rotational forces applied by the CMP process may cause erosion, cracking and peeling of the dielectric material comprising the low-k IMD layer. Additionally, the slurries used by the CMP process may contaminate the substantially porous low-k dielectric material layer.

Thereafter, a wet cleaning process may be used to remove residual slurry material after the CMP process. The wet cleaning process may also include solvents that may be absorbed by the material of the IMD layer. These solvents may also contaminate the IMD layer, as well as any other layers subsequently deposited on such IMD layer, causing the interconnect structure to operate unreliably, sub-optimally or not at all. Removal of absorbed solvents and contaminants from the IMD layer is a time consuming routine that decreases productivity and increases the costs of fabricating the copper interconnect structures.

Therefore, there is a need in the art for an improved method of planarizing a copper interconnect structure.

### SUMMARY OF THE INVENTION

The present invention is a method of forming an interconnect structure (e.g., copper interconnect structure, and the like) on a semiconductor substrate. The interconnect structure is formed by depositing within trenches and openings formed in an inter-metal dielectric (IMD) layer a barrier layer and a conductive material. The interconnect structure is planarized using a two-step process whereby excess conductive material on the IMD material is removed during the first step using a chemical mechanical polishing (CMP) process. In the second step, the barrier layer is removed using a plasma etch process. The barrier layer may be removed using a gas mixture including a halogen-containing gas.

### BRIEF DESCRIPTION OF THE DRAWINGS

The teachings of the present invention can be readily understood by considering the following detailed description in conjunction with the accompanying drawings, in which:

FIG. 1 depicts a flow diagram of a method of planarizing an interconnect structure in accordance with the present invention;

FIGS. 2A-2E depict a sequence of schematic, cross-sectional views of a substrate having an interconnect structure being planarized in accordance with the method of FIG. 1;

FIG. 3 is a schematic, plan view of a processing platform integrating the process chambers used in performing portions of the present invention;

FIG. 4 depicts a schematic diagram of an exemplary plasma etch apparatus of the kind used in performing portions of the inventive method; and

FIG. 5 depicts a schematic diagram of an exemplary plasma stripping apparatus of the kind used in performing portions of the inventive method.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method of planarizing an interconnect structure (e.g., copper interconnect structure, and the like) formed on a semiconductor substrate. The interconnect structure is formed by depositing within trenches and openings formed in an inter-metal dielectric (IMD) layer a barrier layer and a conductive material. Thereafter, the interconnect structure is planarized using a two-step process whereby excess conductive material on the IMD material is removed during the first step using a chemical mechanical polishing (CMD) process. In the second step, the barrier layer is removed using a plasma etch process. The barrier layer is removed using a gas mixture including a halogen-containing gas.

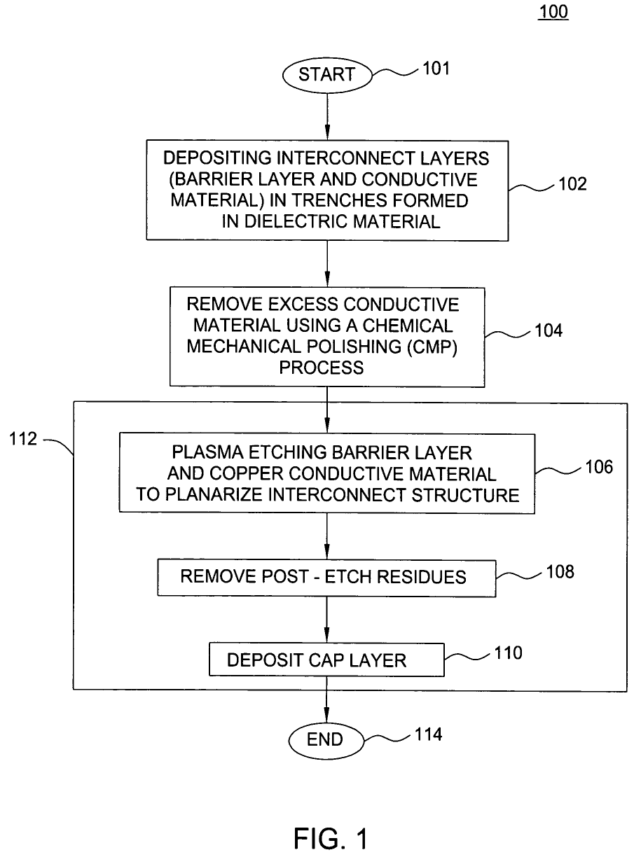

FIG. 1 depicts a flow diagram of one embodiment of the inventive method for planarizing an interconnect structure as sequence 100. The sequence 100 comprises the processes that are performed upon interconnect layers deposited in trenches and openings so as to form the interconnect structure.

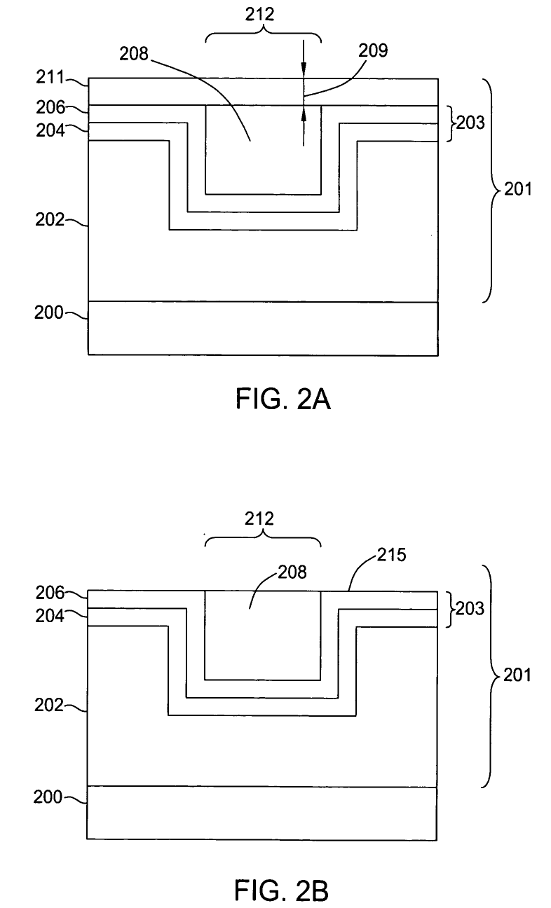

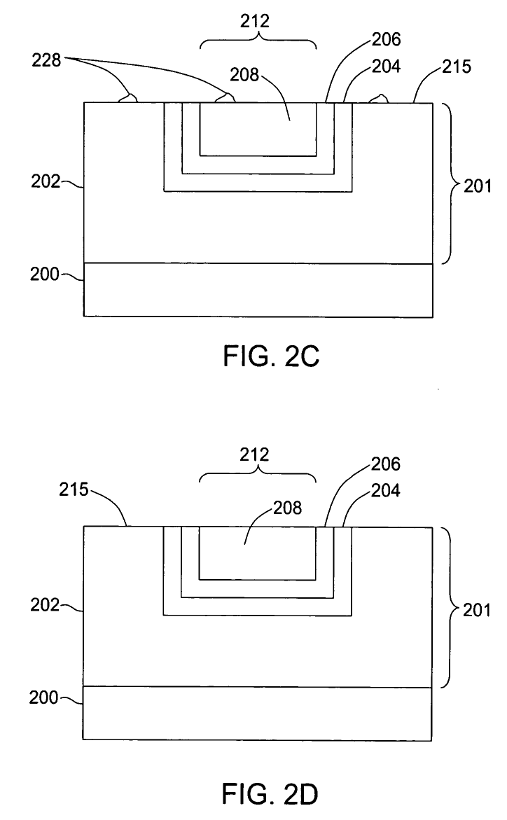

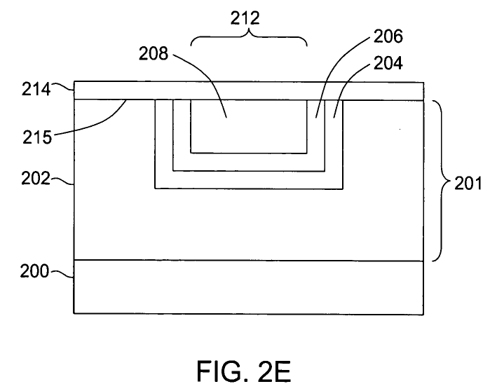

FIGS. 2A-2E depict a sequence of schematic, cross-sectional views of a substrate comprising an interconnect structure being formed using the sequence 100. To best understand the invention, the reader should simultaneously refer to FIG. 1 and FIGS. 2A-2E. The cross-sectional views in FIGS. 2A-2E relate to the processing steps used to planarize the copper interconnect structure. Sub-processes and lithographic routines (e.g., wafer cleaning procedures, and the like) are well known in the art and, as such, are not shown in FIG. 1 and FIGS. 2A-2E. The images in FIGS. 2A-2E are not depicted to scale and are simplified for illustrative purposes.

Processes used to accomplish the sequence 100 can be performed using, for example, respective processing modules of the CENTURA®, PRODUCER®, and other semiconductor wafer processing systems available from Applied Materials, Inc. of Santa Clara, Calif.

The sequence 100 starts at step 101 and proceeds to step 102 wherein material layers 201 comprising a copper interconnect structure are formed on a substrate 200 (e.g., silicon (Si) wafer, and the like) (FIG. 2A).

In one exemplary embodiment, the material layers 201 comprise a dielectric layer 202, a barrier layer 203 and a copper layer 208. Such material layers 201 illustratively represent a wiring layer of an IC device. The wafer 200 may further comprise at least one other wiring layer, which may be considered, with respect to material layers 201, as an underlying wiring layer, as well as comprise other intermediate films or layers between material layers 201 and such underlying layer (all not shown).

The dielectric layer 202 may be formed, e.g., from at least one material having a dielectric constant less than 4.0 (i.e., low-k material), such as organic doped silicon glass (OSG), fluorine doped silicon glass (FSG), organic polymers (e.g., benzocyclobutene, parylene, polytetrafluoroethylene, polyether, polyimide), and the like. The OSG material is commonly referred to in the art as doped silicon dioxide. One OSG material is available under the trademarks BLACK DIAMOND™ and BLACK DIAMOND II™ from Applied Materials, Inc. of Santa Clara, Calif. Alternatively, the layer 202 may be formed from a dielectric material having a dielectric constant greater than 4.0. Generally, the dielectric layer 202 is deposited to a thickness of about 1000 to 5000 Angstroms.

In one embodiment, the barrier layer 203 illustratively comprises two layers, e.g., a first barrier layer 204 formed on the dielectric layer 202 and a second barrier layer 206 formed atop the first barrier layer 204. The layers 204 and 206 may comprise a metal (e.g., tantalum (Ta), titanium (Ti), tungsten (W), and the like) and a nitride of the metal (e.g., tantalum nitride (TaN), titanium nitride (TiN), tungsten nitride (WN), and the like), respectively. Materials used for the first barrier layer 204 and the second barrier layer 206 are selected such that barrier layer 203 improves adhesion between the dielectric layer 202 (e.g., OSG layer) and the copper layer 208, as well as protects the dielectric layer 202 during fabrication of the IC device. The first barrier layer 204 and the second barrier layer 206 are each generally deposited to a thickness of about 50 to 200 Angstroms, while a total thickness of the barrier layer 203 is about 200-350 Angstroms.

The dielectric layer 202 and barrier layer 203 may be deposited using a vacuum deposition technique, such as chemical vapor deposition (CVD), plasma enhanced CVD (PECVD), physical vapor deposition (PVD), evaporation, and the like. Deposition of such layers may be performed using the respective processing reactors of CENTURA®, ENDURA®, and other semiconductor processing systems available from Applied Materials, Inc. of Santa Clara, Calif.

The copper layer 208 may be formed using, e.g., an electroplating (ECP) process. During the electroplating process, copper metallizes (or fills) a feature (e.g., a trench 212) formed in the dielectric layer 202. The ECP process also deposits an excess amount (film 211) of copper on the barrier layer 203 (i.e., on the second barrier layer 206). A thickness 209 for the excess copper film 211 (shown in broken line) of layer 208 is generally about 500 to 1000 Angstroms.

The ECP process can be performed, for example, using the ELECTRAE processing system available from Applied Materials, Inc. of Santa Clara, Calif. In other applications of the invention, the ECP process or other copper deposition process may be used to fill features such as vias, both vias and trenches simultaneously, and the like. As such, the depicted embodiment illustrates only one of many applications for the invention.

At step 104, the film 211 of excess copper is removed using a chemical-mechanical polishing (CMP) process (FIG. 2B). Step 104 does not remove the barrier layer 203. Such CMP process may be conventionally performed using, for example, the MIRRA® processing system available from Applied Materials, Inc. of Santa Clara, Calif. After the CMP process, the wafer 200 is cleaned using a conventional wet cleaning process to remove traces of the slurries and by-products from the CMP process. During the wet cleaning process, the barrier layer 203 protects the dielectric layer 202 from exposure to and contamination from solvents used during such process.

At step 106, the barrier layer 203 (e.g., first barrier layer 204 and second barrier layer 206) is plasma etched and removed from the surface 215 of the dielectric layer 202 (FIG. 2C). Using a plasma etch process to remove the barrier layer 203, the inventive method protects the dielectric layer 202 from exposure to slurries used during the CMP process, as well as from exposure to solvents used during the post-CMP wet cleaning process (discussed above with reference to step 104).

Step 106 may use the dielectric layer 202 as an etch stop layer. To determine the endpoint of the etch process, the etch reactor may use an endpoint detection system to monitor plasma emissions at a particular wavelength, laser interferometry, control of process time, and the like. The method of claim 11 further comprising plasma stripping post-etch residues after step (c).

In one embodiment, a barrier layer 203 composing tantalum (Ta) or tantalum nitride (TaN) is etched using a fluorine-containing chemistry, e.g., a gas (or gas mixture) comprising at least one fluorocarbon gas such as C_{X}F_{Y} where x and y are integers (e.g., carbon tetrafluoride (CF₄)) or C_{X}H_{Y}F_{Z} where x, y, and z are integers (e.g., difluoromethane (CH₂F₂), trifluoromethane (CHF₃)), sulfur hexafluoride (SF₆), nitrogen trifluoride (NF₃), and the like. Herein the terms “gas” and “gas mixture” are used interchangeably. Further, the gas may also comprise a diluent gas, such as at least one of argon (Ar) and helium (He). Such fluorine-containing chemistry has a tunable etch selectivity to copper (layer 208) as well as for a low-k dielectric material, e.g., BLACK DIAMOND™ or BLACK DIAMOND II™ (layer 202).

In an alternative embodiment, the barrier layer comprising tantalum (Ta) or tantalum nitride (TaN) may be etched using a chlorine-containing chemistry, e.g., a gas comprising hydrogen chloride (HCl) and an hydrocarbon additive gas, such as C_{X}H_{Y} where x and y are integers (e.g., methane (CH₄), ethane (C₂H₆)), and the like, as well as a diluent gas, such as at least one inert gas, e.g., argon (Ar), helium (He), and the like. The chlorine-containing chemistry has a tunable etch selectivity to copper and the low-k dielectric material, as well as a wide process window for copper corrosion resistance.

In yet another alternative embodiment, the barrier layer of step 106 may be etched using a combination of the fluorine-containing chemistry and chlorine-containing chemistry.

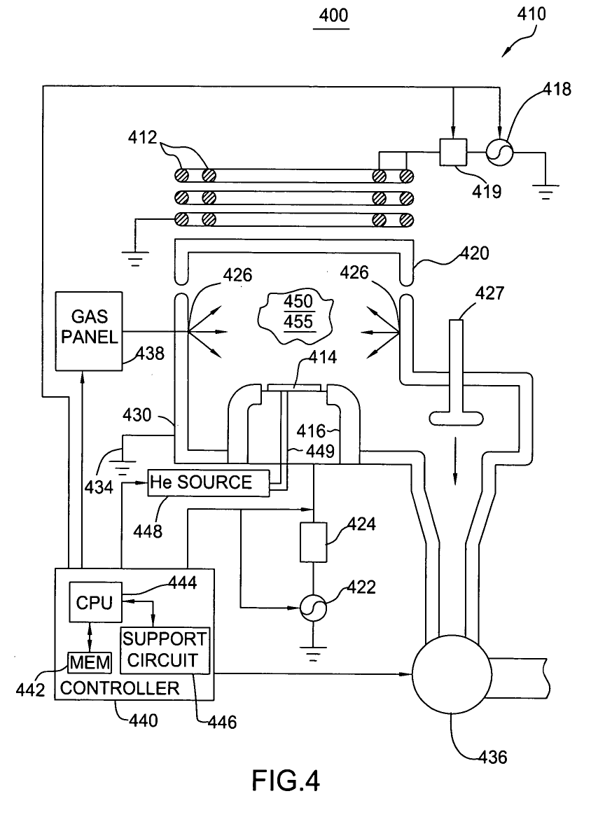

Step 106 can be performed in an etch reactor such as a Decoupled Plasma Source (DPS) II module of the CENTURA® processing system, available from Applied Materials, Inc. of Santa Clara, Calif. In one embodiment, the DPS II module (described below with reference to FIG. 4) uses a 2 MHz inductive source to produce a high-density plasma.

In one illustrative embodiment, the barrier layer 203 comprising a tantalum film 204 and a tantalum nitride film 206 is etched using the DPS II module by providing nitrogen trifluoride (NF₃) at a flow rate of 30 to 200 sccm, applying power to an inductively coupled antenna between 300 and 2000 W, applying a cathode bias power between 0 and 50 W, and maintaining a wafer pedestal temperature of about 200 to 400 degrees Celsius at a pressure in the process chamber of between 3 and 100 mTorr. One illustrative etch process provides nitrogen trifluoride (NF₃) at a flow rate of 50 sccm, applies 600 W of power to the inductively coupled antenna, 0 W of cathode bias power and maintains a wafer pedestal temperature of 240 degrees Celsius at a chamber pressure of 30 mTorr. Such a process provides etch selectivity for tantalum (Ta) and tantalum nitride (TaN) (layer 203) over BLACK DIAMOND™ or BLACK DIAMOND II™ (layer 202) of at least 15:1, as well as etch selectivity for copper (layer 208) over tantalum (Ta) and tantalum nitride (TaN) of about 1:1.

Step 106 simultaneously removes an exposed portion of the barrier layer 203 and planarizies the copper layer 208 to be coplanar with the surface 215 of the dielectric layer 202. However, step 106 may leave post-etch residue 228 (e.g., copper-fluoride and copper-chloride residue) on the dielectric layer 202, as well as elsewhere on the substrate 200 (FIG. 2C).

At step 108, the post-etch residue 228 is removed from the substrate 200 (FIG. 2D). Step 108 uses a plasma strip process that transforms the post-etch residue 228 into volatile gaseous compounds that are then pump evacuated from the processing chamber. Such plasma strip process may use a gas comprising at least one of ammonia (NH₃), nitrogen (N₂), hydrogen (H₂), water vapor (H₂O), and the like.

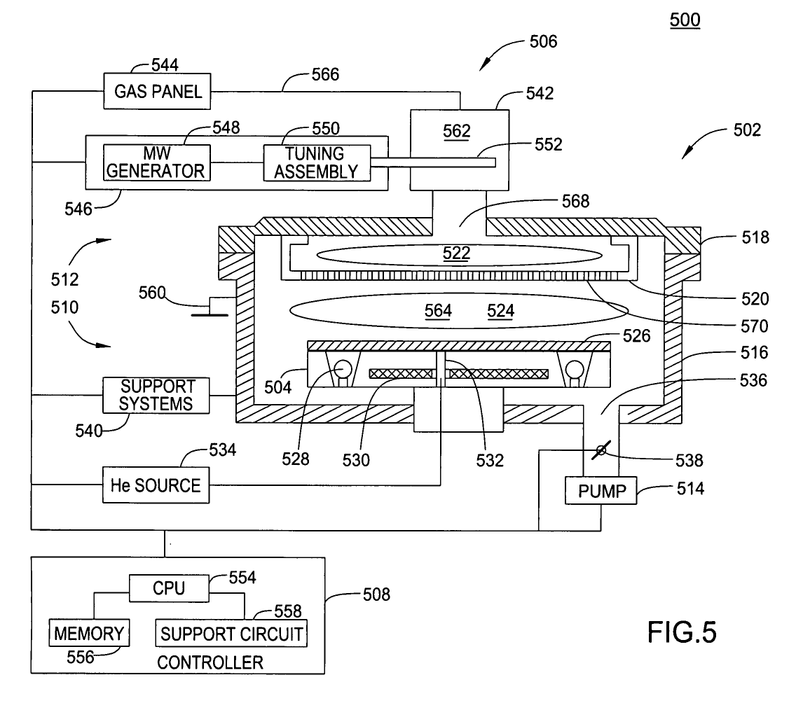

Step 108 may be performed using, e.g., a plasma stripping reactor, such as the Advanced Strip and Passivation (ASP) module of the CENTURA® processing system. The ASP module (described below with reference to FIG. 5) is a microwave downstream plasma reactor in which the plasma is confined such that only reactive neutrals are allowed to enter the process chamber, thereby precluding plasma-related damage of the substrate or circuits formed on the substrate.

Alternatively, step 108 may be performed using the AXIOM® module of the PRODUCER® processing system. The AXIOM® module is a remote plasma reactor that is described in detail in U.S. patent application Ser. No. 10/264,664, filed Oct. 4, 2002 (Attorney docket number 6094), which is herein incorporated by reference.

Upon completion of the preceding etch process (step 106), the wafer 200 is transferred from the etch reactor (e.g., DPS II module) to the remote plasma stripping reactor (e.g., ASP module) using a vacuumed wafer transport. Specifically, the wafer 200 is transferred without exposing the wafer to a non-vacuumed portion of the manufacturing environment.

In one embodiment, both the DPS II module (step 106) and the ASP module (step 108) are components of same CENTURA® processing system, and the wafer 200 is transferred using a wafer robot operating in a vacuumed interior of such processing system. In such an embodiment, the dielectric layer 202 (e,g., low-k layer) is protected from contaminants that are present in the non-vacuumed portion of the manufacturing environment. Additionally, use of the wafer robot of the processing system for transporting the wafer between the processing modules decreased the time of the transportation and, as such, increases productivity of fabricating the copper interconnect structure.

In an alternative embodiment including the PRODUCER® processing system, the wafer 200 is transferred, without exposing the wafer to a non-vacuumed portion of the manufacturing environment, from the PRODUCER® etch module (step 106) to the AXIOM® module (step 108) using a wafer robot.

In one illustrative embodiment, post-etch residue 228 comprising copper-fluoride compounds and tantalum fluoride compounds is removed using the ASP module by providing ammonia (NH₃) at a flow rate of 50 to 4000 sccm, nitrogen (N₂) at a flow rate of 0 to 4000 sccm (i.e., a NH₃:N₂ flow ratio ranging from 1:80 to all NH₃), argon (Ar) or helium (He) at a flow rate of 0 to 4000 sccm, applying microwave power between 500 and 3000 W, and maintaining a wafer pedestal temperature of about 200 to 400 degrees Celsius at a pressure in the process chamber of between 200 to 4000 mTorr. One illustrative process provides ammonia (NH₃) at a flow rate of 1000 sccm, nitrogen (N₂) at a flow rate of 1000 sccm (i.e., a NH₃: N₂ flow ratio of about 1:1), applies 1200 W of microwave power and maintains a wafer pedestal temperature of 300 degrees Celsius at a pressure of 2000 mTorr.

At step 110, a cap layer 214 is formed upon the film stack 201 (FIG. 2E). The cap film 214 generally comprises a dielectric material, such as silicon nitride (Si₃N₄), and the like and is formed to a thickness of about 20 to 100 Angstroms. Such a layer may be conventionally formed using a chemical vapor deposition (CVD) or plasma enhanced CVD (PECVD) reactor, e.g., Dxe module of the CENTURA® processing system or, alternatively, the SE CVD module of the PRODUCER® processing system.

The DxZ® module is a PECVD reactor suitable for depositing a broad range of materials. The DxZ® module is available from Applied Materials, Inc. and is disclosed in commonly assigned U.S. Pat. No. 6,364,954 B2, issued Apr. 2, 2002, which is incorporated herein by reference. The SE CVD module is a PECVD reactor comprising a process chamber having two isolated processing regions. Each of the processing regions may be used to deposit dielectric and other materials. The SE CVD module is also available from Applied Materials, Inc. of Santa Clara, Calif. and is disclosed in commonly assigned U.S. Pat. No. 5,855,681, issued Jan. 5, 1999.

In one embodiment, the ASP module (step 108), the DxZ module (step 110), as well as the DPS II module (step 106), are all components of same CENTURA® processing system. Upon completion of step 108, the wafer 200 is transferred from the plasma stripping reactor (e.g., ASP module) to the CVD or PECVD module (e.g., DxZ® module) using the wafer robot operating in a vacuumed interior of the processing system, as discussed above in reference to step 106. As such, during transportation between the processing modules, the wafer is protected from exposure to a non-vacuumed portion of the manufacturing environment.

In an alternative embodiment, using the PRODUCER® processing system, the wafer 200 may be transferred, using such a robot, from the AXIOM® module (step 108) to the SE CVD module (step 110) of the same processing system. In one embodiment, the PRODUCER® etch module (step 106), the AXIOM® module, and the PRODUCER® SE CVD module are components of same PRODUCER® processing system, and, during transportation between the modules, the wafer 200 stays within the vacuumed interior of the processing system.

Steps 106, 108, and 110, together, comprise a processing sequence 112 that facilitates an integrated solution for planarizing a copper interconnect structure using the described above plasma processes. The processing sequence 112 provides best performance, productivity, and costs benefits when performed using the processing modules which are all components of the same semiconductor wafer processing system (e.g., CENTURA® or PRODUCER® processing system) having a vacuumed wafer interface between such processing modules.

As readily appreciated by those skilled in the art, commonality of interfaces between a processing module and a processing system allows use of various processing modules, including modules of different processing systems, within one such processing system. As such, the discussed above illustrative configurations of the exemplary CENTURA® and PRODUCER® processing system should not be considered as limiting the scope of the present invention. In alternative embodiments, the processing systems may comprise either different processing modules or at least one same module. For example, in one illustrative embodiment, the AXIOM® module may be used as a component of the CENTURA® processing system, as well as the ASP module may be a component of the PRODUCER® processing system.

At step 114, the sequence 100 ends.

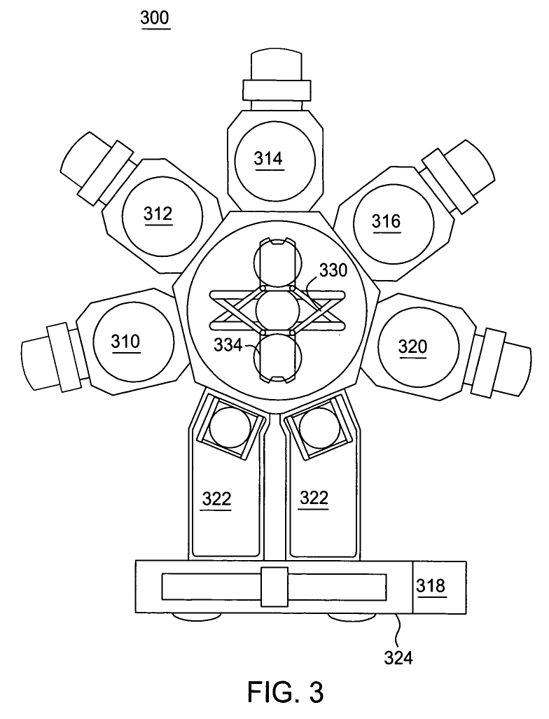

FIG. 3 is a schematic, top plan view of an exemplary integrated processing system 300 configured for planarizing a copper interconnect structure using the processing sequence 112 of the present invention. One such integrated processing system is the CENTURA® processing system available from Applied Materials, Inc. of Santa Clara, Calif. The particular embodiment of the system 300 is provided to illustrate the invention and should not be used to limit the scope of the invention.

The integrated processing system 300 generally includes load lock chambers 322 that protect vacuumed interior of the system 300 from contaminants. A robot 330 having a blade 334 is used to transfer the substrates between the load lock chambers 322 and the process modules 310, 312, 314, 316, 320. At least one of such modules is the DPS II module, the ASP module, and the DxZ® module, as discussed above in reference to steps 106, 108, and 110, respectively. Further, the system 300 may comprise other processing module, e.g. the RADIANCE™ thermal processing module, available from Applied Materials, Inc. of Santa Clara, Calif. Further, the system 300 may comprise one or more metrology chambers 318 connected thereto using, e.g., a factory interface 324. Alternatively, the system 300 may comprise other types of process chambers.

One example of a possible configuration for the integrated processing system 300 includes a load lock chamber (chamber 322), the DPS II modules (module 310, 312), the ASP modules (module 314, 316), and DXZ® module (module 320).

FIG. 4 depicts a schematic diagram of an exemplary Decoupled Plasma Source (DPS) II etch reactor 400 that may be used to practice portions of the invention. The DPS II reactor is available from Applied Materials, Inc. of Santa Clara, Calif.

The reactor 400 comprises a process chamber 410 having a wafer support pedestal 416 within a conductive body (wall) 430, and a controller 440.

The chamber 410 is supplied with a substantially flat dielectric ceiling 420. Other modifications of the chamber 410 may have other types of ceilings, e.g., a dome-shaped ceiling. Above the ceiling 420 is disposed an antenna comprising at least one inductive coil element 412 (two co-axial elements 412 are shown). The inductive coil element 412 is coupled, through a first matching network 419, to a plasma power source 418. The plasma source 418 typically is capable of producing up to 4000 W at a tunable frequency in a range from 50 kHz to 13.56 MHz.

The support pedestal (cathode) 416 is coupled, through a second matching network 424, to a biasing power source 422. The biasing source 422 generally is a source of up to 500 W at a frequency of approximately 13.56 MHz that is capable of producing either continuous or pulsed power. In other embodiments, the source 422 may be a DC or pulsed DC source.

A controller 440 comprises a central processing unit (CPU) 444, a memory 442, and support circuits 446 for the CPU 444 and facilitates control of the components of the etch chamber 410 and, as such, of the etch process, as discussed below in further detail.

In operation, a semiconductor wafer 414 is placed on the pedestal 416 and process gases are supplied from a gas panel 438 through entry ports 426 to form a gaseous mixture 450. The gaseous mixture 450 is ignited into a plasma 455, in the chamber 410, by applying power from the plasma source 418 and the bias source 422 to the inductive coil element 412 and the cathode 416, respectively. The pressure within the interior of the chamber 410 is controlled using a throttle valve 427 and a vacuum pump 436. Typically, the chamber wall 430 is coupled to an electrical ground 434. The temperature of the wall 430 is controlled using liquid-containing conduits (not shown) that run through the wall 430.

The temperature of the wafer 414 is controlled by stabilizing a temperature of the support pedestal 416. In one embodiment, helium gas from a gas source 448 is provided via a gas conduit 449 to channels formed by the back of the wafer 414 in the pedestal surface. The helium gas is used to facilitate heat transfer between the pedestal 416 and the wafer 414. During processing, the pedestal 416 may be heated by a resistive heater (not shown) within the pedestal to a steady state temperature and then the helium gas facilitates uniform heating of the wafer 414. Using such thermal control, the wafer 414 is maintained at a temperature of between 0 and 500 degrees Celsius.

Those skilled in the art will understand that other forms of etch chambers may be used to practice the invention, including chambers with remote plasma sources, electron cyclotron resonance (ECR) plasma chambers, and the like.

To facilitate control of the process chamber 410 as described above, the controller 440 may be one of any form of general-purpose computer processor that can be used in an industrial setting for controlling various chambers and sub-processors. The memory 442, or computer-readable medium, of the CPU 444 may be one or more of readily available memory such as random access memory (RAM), read only memory (ROM), floppy disk, hard disk, or any other form of digital storage, local or remote. The support circuits 446 are coupled to the CPU 444 for supporting the processor in a conventional manner. These circuits include cache, power supplies, clock circuits, input/output circuitry and subsystems, and the like. The inventive method is generally stored in the memory 442 as a software routine. The software routine may also be stored and/or executed by a second CPU (not shown) that is remotely located from the hardware being controlled by the CPU 444.

FIG. 5 depicts a schematic diagram of an exemplary ASP reactor 500 that may be used to practice portions of the invention. The ASP reactor is available from Applied Materials, Inc. of Santa Clara, Calif. The reactor 500 comprises a process chamber 502, a remote plasma source 506, and a controller 508.

The process chamber 502 generally is a vacuum vessel, which comprises a first portion 510 and a second portion 512. In one embodiment, the first portion 510 comprises a substrate pedestal 504, a sidewall 516 and a vacuum pump 514. The second portion 512 comprises a lid 518 and a gas distribution plate (showerhead) 520, which defines a gas mixing volume 522 and a reaction volume 524. The lid 518 and sidewall 516 are generally formed from a metal (e.g., aluminum (Al), stainless steel, and the like) and electrically coupled to a ground reference 560.

The substrate pedestal 504 supports a substrate (wafer) 526 within the reaction volume 524. In one embodiment, the substrate pedestal 504 may comprise a source of radiant heat, such as gas-filled lamps 528, as well as an embedded resistive heater 530 and a conduit 532. The conduit 532 provides a gas (e.g., helium) from a source 534 to the backside of the wafer 526 through grooves (not shown) in the wafer support surface of the pedestal 504. The gas facilitates heat exchange between the support pedestal 504 and the wafer 526. The temperature of the wafer 526 may be controlled between about 20 and 400 degrees Celsius.

The vacuum pump 514 is coupled to an exhaust port 536 formed in the sidewall 516 of the process chamber 502. The vacuum pump 514 is used to maintain a desired gas pressure in the process chamber 502, as well as evacuate the post-processing gases and other volatile compounds from the chamber. In one embodiment, the vacuum pump 514 comprises a throttle valve 538 to control a gas pressure in the process chamber 502.

The process chamber 502 also comprises conventional systems for retaining and releasing the wafer 526, detecting an end of a process, internal diagnostics, and the like. Such systems are collectively depicted in FIG. 5 as support systems 540.

The remote plasma source 506 comprises a microwave power source 546, a gas panel 544, and a remote plasma chamber 542. The microwave power source 546 comprises a microwave generator 548, a tuning assembly 550, and an applicator 552. The microwave generator 548 is generally capable of producing up to about 200 W to 3000 W at a frequency of about 0.8 to 3.0 GHz. The applicator 552 is coupled to the remote plasma chamber 542 to energize a process gas (or gas mixture) 564 in the remote plasma chamber 542 into a microwave plasma 562.

The gas panel 544 uses a conduit 566 to deliver the process gas 564 to the remote plasma chamber 542. The gas panel 544 (or conduit 566) comprises means (not shown), such as mass flow controllers and shut-off valves, to control gas pressure and flow rate for each individual gas supplied to the chamber 542. In the microwave plasma 562, the process gas 564 is ionized and dissociated to form reactive species.

The reactive species are directed into the mixing volume 522 through an inlet port 568 in the lid 518. To minimize charge-up plasma damage to devices on the wafer 526, the ionic species of the process gas 564 are substantially neutralized within the mixing volume 522 before the gas reaches the reaction volume 524 through a plurality of openings 570 in the showerhead 520.

The controller 508 comprises a central processing unit (CPU) 554, a memory 556, and a support circuit 558. The CPU 554 may be one of any form of a general-purpose computer processor used in an industrial setting. Software routines can be stored in the memory 556, such as random access memory, read only memory, floppy or hard disk, or other form of digital storage. The support circuit 558 is conventionally coupled to the CPU 554 and may comprise cache, clock circuits, input/output sub-systems, power supplies, and the like.

The software routines, when executed by the CPU 554, transform the CPU into a specific purpose computer (controller) 508 that controls the reactor 500 such that the processes are performed in accordance with the present invention. The software routines may also be stored and/or executed by a second controller (not shown) that is located remotely from the reactor 500.

The invention may be practiced using other semiconductor wafer processing systems wherein the processing parameters may be adjusted to achieve acceptable characteristics by those skilled in the art utilizing the teachings disclosed herein without departing from the spirit of the invention.

Although the forgoing discussion referred to fabrication of the copper interconnect structure, fabrication of the other devices and structures used in the integrated circuits can benefit from the invention.

While foregoing is directed to the illustrative embodiment of the present invention, other and further embodiments of the invention may be devised without departing from the basic scope thereof, and the scope thereof is determined by the claims that follow.

1. A method of forming an interconnect structure comprising:
(a) providing a dielectric layer on a substrate having a barrier layer and conductive material deposited thereon in at least one interconnect opening formed in the dielectric layer;
(b) removing excess conductive material deposited on a top surface of the barrier layer using a chemical mechanical polishing process; and
(c) removing excess barrier layer from the top surface of the dielectric layer to form an interconnect structure using a plasma comprising a halogen-containing gas.

2. The method of claim 1 wherein the conductive material comprises copper (Cu).

3. The method of claim 1 wherein the barrier layer comprises at least one film of tantalum (Ta), tantalum nitride (TaN), titanium (Ti), titanium nitride (TiN), tungsten (W) and tungsten nitride (WN).

4. The method of claim 1 wherein the dielectric layer comprises at least one of carbon doped silicon oxide, organic doped silicon glass and fluorine doped silicon glass.

5. The method of claim 1 further comprising forming a cap layer on the interconnect structure after the excess barrier layer is removed.

6. The method of claim 5 wherein the cap layer comprises a dielectric material.

7. The method of claim 5 wherein the cap layer comprises silicon nitride (Si₃N₄).

8. The method of claim 1 further comprising plasma stripping post-etch residues after step (c).

9. The method of claim 1 wherein the halogen-containing gas comprises one or more gases selected from the group consisting of CₓF_{y} where x and y are integers, CₓH_{y}F_{z} where x, y and z are integers, sulfur hexafluoride (SF₆), nitrogen trifluoride (NF₃) and hydrogen chloride (HCl).

10. (Cancelled)

11. A method of forming a copper interconnect structure comprising:
(a) providing a dielectric layer on a substrate having a barrier layer and copper deposited thereon in at least one interconnect opening formed in the dielectric layer;
(b) removing excess copper deposited on a top surface of the barrier layer using a chemical mechanical polishing process; and
(c) removing excess barrier layer from the top surface of the dielectric layer to form an interconnect structure using a plasma comprising a halogen-containing gas.

12. The method of claim 11 wherein the barrier layer comprises at least one film of tantalum (Ta), tantalum nitride (TaN), titanium (Ti), titanium nitride (TiN), tungsten (W) and tungsten nitride (WN).

13. The method of claim 11 wherein the dielectric layer comprises at least one of carbon doped silicon oxide, organic doped silicon glass and fluorine doped silicon glass.

14. The method of claim 11 further comprising forming a cap layer on the copper interconnect structure after the excess barrier layer is removed.

15. The method of claim 14 wherein the cap layer comprises a dielectric material.

16. The method of claim 14 wherein the cap layer comprises silicon nitride (Si₃N₄).

17. The method of claim 11 further comprising plasma stripping post-etch residues after step (c).

18. The method of claim 11 wherein the halogen-containing gas comprises one or more gases selected from the group consisting of CₓF_{y} where x and y are integers, CₓH_{y}F_{z} where x, y and z are integers, sulfur hexafluoride (SF₆), nitrogen trifluoride (NF₃) and hydrogen chloride (HCl).

19. (Cancelled)

20. A method of forming a copper interconnect structure comprising:
a) providing a low dielectric constant layer on a substrate having a barrier layer and copper deposited thereon in at least one interconnect opening formed in the low dielectric constant layer:
(b) removing excess copper deposited on a top surface of the barrier layer using a chemical mechanical polishing process; and
(c) removing excess barrier layer from the top surface of the low dielectric constant layer to form an interconnect structure using a plasma comprising a halogen-containing gas.

21. The method of claim 20 wherein the barrier layer comprises at least one film of tantalum (Ta), tantalum nitride (TaN), titanium (Ti), titanium nitride (TiN), tungsten (W) and tungsten nitride (WN).

22. The method of claim 20 wherein the halogen-containing gas comprises one or more gases selected from the group consisting of CₓF_{y} where x and y are integers, CₓH_{y}F_{z} where x, y and z are integers, sulfur hexafluoride (SF₆), nitrogen trifluoride (NF₃) and hydrogen chloride (HCl).

23. The method of claim 20 further comprising plasma stripping post-etch residues after step (c).
